(19) United States
(12) Patent Application Publication
(10) Pub. No.: US 2002/0089000 A1
(43) Pub. Date: Jul. 11, 2002

(54) Bipolar static induction transistor (variants)

(76) Inventor: Solomon Edlin, Rishon Le Zion (IL)

Correspondence Address: EDLIN SOLOMON, ST. SHAPIRA 5/3, RISHON LE ZION, 75284, IL

(21) Appl. No.: 09/871,383

(22) Filed: May 31, 2001

(30) Foreign Application Priority Data
Jun. 9, 2000 (RU) 2000115115

(51) Int. Cl. H01L 29/76

(52) U.S. Cl. 257/241; 257/213; 257/287

(57) ABSTRACT

The invention relates to a microelectronics and more particularly to a bipolar static induction transistor.

The invention allows to create the transistor which can operate on supply pressure 220 volt and over, that is the transistor can be both close and open, with any polarity of a voltage on drain-source. It simplifies designing of many circuits and makes it possible to create circuits which cannot be produced with any other types of transistors. Besides, the transistor has high technical characteristics: high current density and high switching power. It makes it possible to apply the transistor for production, transfer and use of electric energy.

This is achieved by disposing elements of the bipolar static induction transistor—a gate, a source and a channel—on each of sides of a substrate.

The invention is explained with three drawings.

The invention relates to a microelectronics and more particularly to a bipolar static induction transistor.

There exists a bipolar static induction transistor comprising elements of a bipolar static induction transistor—a gate, a source and a channel—on one of sides of the substrate, and elements of a onejunction transistor—an emitter and a base (drain)—on the other [1]. This transistor has high current density and can switch high power. The drawback of the transistor is that it cannot operate on circuits of alternating voltage (to be more precise, it can only be closed by supplying one of polarities of the drain-source voltage).

There exists a bipolar transistor, which has structure actually comprising two bipolar transistors and which can operates in alternating-voltage circuit [2]. The drawback of the transistor is that it cannot has high technical characteristics. Its breakdown voltage, current density and switch power are low.

The advantage of the transistor offered is that it can operate in alternating-voltage circuit 220 V and over, which means that it can be both closed and open with any voltage polarity and have high technical characteristics at that—high current density and high switch power.

This result is achieved by disposing elements of the bipolar static induction transistor—a gate, a source and a channel—as well as electrodes and isolation on each of the sides of a substrate.

This result is achieved by one of the channels of the multielemental structure on each of the sides of the substrate is thicker than other channels and connected to a separate electrode.

This result is achieved by disposing an epitaxial layer on each of the sides of the lightly doped substrate of the same type of conductivity with the impurity concentration about 10¹⁷ cm⁻³ in which elements of the bipolar static induction transistor—a gate, a source and a channel—as well as electrodes and the isolation are disposed.

The transistors offered can be applied for production, transfer and use of electric energy within a very broad range of power: from the control of electrical soldering to the control of most powerful turbogenerators. They are effective for designing electronic transformators, power supply units, and “flexible transfers of alternating current”. In the latter case transistors can be connected in series, which will allow to easily create high voltage system with operating voltage 10⁶ V and over with a control with light signals. These transistors can be most widely used in the devices aimed at defending people from electric shock. They can also be used in systems with the unipolar power supply transmitting energy in both directions—both from a source to a load and from a load to a source. It will make it possible to increase circuit efficiency with the voltage drop between a drain and source of the open transistor not exceeding 0.5 V and, if necessary, it can be close to zero.

The structure of the transistor offered is symmetric which means that on each of the sides of a lightly doped n-type substrate with the impurity concentration being 10¹⁴ cm⁻³ there are areas of p⁺-gate, a n⁺-source and n-channel as well as electrodes of gate and source (drain). Owing to the structure symmetry, the output voltage-current characteristics of the transistor are symmetric and are in the first and the third quadrants. Because of this, source and drain of the transistor can change places and transistor can operate in alternating voltage circuits of supply pressure of 220 V and over which simplifies designing of many circuits and besides can be applied in the circuits which cannot be produced with any other types of transistors.

Though the structure of the transistor is symmetric the operating duty of the channel that is near the drain of the transistor essentially differs from the operating duty of the channel that is near its source. The electrical field reduces the concentration of holes in the former and increases their concentration in the latter. Owing to this, the hole concentration along an axis perpendicular to surface is trapezioidal in zero approximation. It puts certain restrictions both on the design parameters of BSIT and on designing of circuits in which these transistors are applied. Algorithm of control of the transistor offered under typical circumstances is more complicated than that of the transistor described above [1]. To achieve optimum characteristics three rather than two different levels voltages should be applied to the transistor gates. One of the voltages to the gate is about zero relatively to the nearby source, with the transistor channel closed, while the voltage applied to the gate near the drain should be about 0.4 V with the channel slightly open and the gate emitting very low hole current to the lightly doped area. When changing polarity of the voltage applied, the source and the drain change places, and the voltages to the gate should be changed accordingly if transistor is to remain closed. In this case the transistor can maintain voltages up to several kilovolt depending on parameters of the lightly doped area. Another voltage on the gates is about 0.8 V relatively of the sourse and drain which are nearby. It provides the opening of the channel and holes emission to the lightly doped area. The emission of holes to the lightly doped area is followed by electrons from the transistor source which makes the hole concentration and electron concentration practically the same in the zero approximation and may reach the magnitude of 10¹⁷÷10¹⁸ cm⁻³; resistance of the transistor drops sharply due to conductivity modulation and the voltage between the drain and the source of the transistor does not exceed 0.5 V at current density ≈1000 a cm⁻². The level of 0.4 V can be substituted by smoothly lowering voltage on the gate which is near the source of the transistor during the switching of the transistor from on condition to off condition.

To have completely controllable transistor (without latch), the BSITs offered should have the channel with low resistance. To this end, thickness of the channel should be small and the impurity concentration near the gate should be high enough so that the electronic current flowing near the gate could not cause a large voltage drop which, in turn, could lead to emission of holes. To meet these requirements, it is desirable to grow an epitaxial layer with donor impurity concentration being about 10¹⁷ cm⁻³ on the surface of the lightly doped substrate having the donor impurity concentration about 10¹⁴ cm⁻³, and to have an equipment with higher resolution than is generally used for manufacturing other BSITs. On the surface of a monocristalline silicon a layer of a polysilicon may be disposed that would help to form the elements of the transistor—the gate, the source, the channel and the electrodes.

The control signals on the gates of the transistor should depend on polarity of the supply voltage (as a rule, it is alternating voltage with the frequency 50-60 Hz) and on the voltage supplied at the moment to the transistor; to do so, it is desirable to introduce to the transistor structure two normally-on transistors with small saturation current which help to fix the polarity of the voltage on the transistor at that moment. Signals from these transistors are transmitted to the control circuit which produces control signals to the gates.

Driver transistors should be disposed on other substrates “bonded” with the main one. Most suitable transistors for the driver are low-voltage bipolar static induction transistors. Due to their small size, their resistance is low enough when in the on-condition; they also have high gain and high speed to control a power transistor. Such transistors can be controlled by light signals with the help of photodiodes.

In a zero approximation, the transistor offered does multiplication of voltages applied to the transistor gates and drains and can be considered as double-band modulator and be used, for example, to control polarity of rectified voltage.

Apart from the main purpose-application, that is using the transistor as a completely controllable power bidirectional key, a similar structure can be used for other purposes; to achieve these purposes, both the control of emission and of extraction of holes into lightly doped area are used, as well as current feedback for the control of emission (for example, latch when manufacturing a swithboard).

The transistor with an offered combination of features is unknown, therefore the offered transistor is corresponding to a criterion “novelty”.

The offered combination of features does not obviously follow from the engineering level, therefore the transistor is corresponding to a criterion “invention level”.

The purpose of the invention and the means and methods of its realization are indicated in the application documents, its purpose being realizable,—which means there is “industrial applicability”.

Inventions is explained with three drawings.

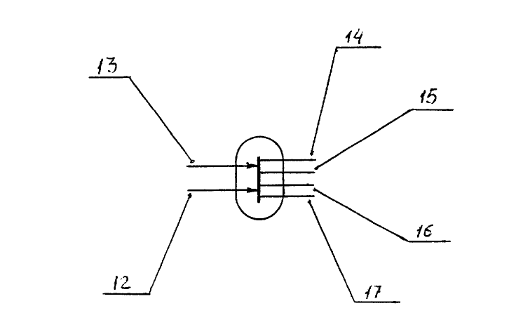

FIG. 1 represents a bipolar static induction transistor structure.

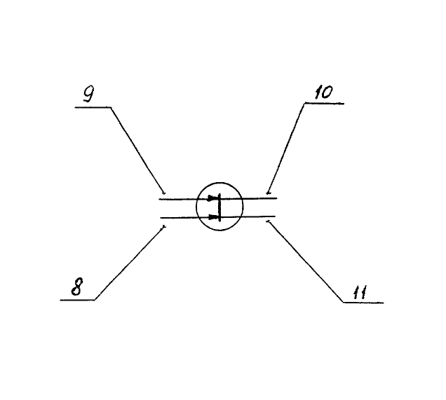

FIG. 2 represents a symbolic image offered of the transistor.

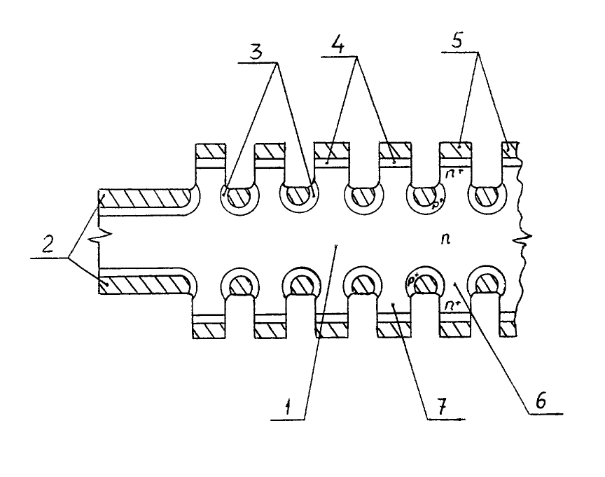

FIG. 3 represents a symbolic image offered of the power normally-off transistor with two lowpower normally-on transistors.

Bipolar static induction transistor comprises lightly doped n-type substrate 1, gate electrodes 2, gate 3, n⁺-type polysilicon 4, drain electrode 5, channel 6, source 7.

Symbolic image of transistor comprises gates 8, 9; drains (sources) 10, 11.

Symbolic image of power normally-off transistor with two lowpower normally-on transistors comprises gates 12, 13; drains (sources) of lowpower transistors 14, 17; drains (sources) of a power transistor 15, 16.

The transistor offered can be named “symmetric channel tetrod”.

The transistor offered can be manufactured, for example, in accordance with the method described in application of this author RF No97101134 “Method of manufacture of semiconductor devices” and also by using the technology of “bonding” substrates with the help of metallid layer.

Improvement of characteristics of the transistor can be achieved by using it under the temperature of liquid nitrogen.

1. Transistor comprising elements of a bipolar static induction transistor—a gate, a source and a channel—on each of the sides of a substrate.

2. Transistor according to claim 1 differing in that one of the channels of multielement structures on each of the sides of the substrate is thicker than other channels, and this channel is connected to a separate electrode.

3. Transistor comprising on each of the sides of a lightly doped substrate an epitaxial layer of the same type of conductivity with the impurity concentration of about 10¹⁷ cm⁻³, in which elements of a bipolar static induction transistor—a gate, a sourse and a channel—are disposed.

4. Transistor according to claim 3 differing in that one of the channels of multielement structures on each of sides of the substrate is thicker than other channels, and this channel is connected to a separate electrode.
